(19) United States
(12) Patent Application Publication
(10) Pub. No.: US 2006/0102226 A1
(43) Pub. Date: May 18, 2006

(54) Method for producing the photoelectrode of a solar cell

(75) Inventors: Rainer Kern, Stuttgart (DE); Peter Nitz, Gundelfingen (DE); Sarmimala Hore, Stuttgart (DE)

Correspondence Address: Breiner & Breiner, L.L.C., P.O. Box 19290, Alexandria, VA, 22320-0290, US

(73) Assignees: Fraunhofer-Gesellschaft zur Forderung der angewandten Forschung e.V., Munchen (DE); Albert-Ludwigs-Universitat Freiburg, Freiburg (DE)

(21) Appl. No.: 11/265,127

(22) Filed: Nov. 3, 2005

(30) Foreign Application Priority Data
Nov. 12, 2004 (DE) 10 2004 054 757.2

(51) Int. Cl. H01L 25/00

(52) U.S. Cl. 136/246

(57) ABSTRACT

The invention relates to a method for producing the photoelectrode of a solar cell in which a layer of a nanocrystalline semiconductor material is applied on a substrate and then sintered at a sintering temperature. In the method, elongated particles which burn out at the sintering temperature and leave elongated cavities in the layer are introduced into the layer. The invention also relates to a solar cell having a photoelectrode which has such type cavities. The method permits producing photoelectrodes for dye solar cells which allow sufficient diffusion of the electrolyte into the photoelectrode and thus a sufficiently great photocurrent even in the case of high viscous electrolytes.

### FIELD OF INVENTION

The present invention relates to a method for producing the photoelectrode of a solar cell in which a layer of a nanocrystalline semiconductor material is applied to a substrate and then sintered at a sintering temperature. The present invention also relates to a solar cell having a photoelectrode which is producible according to the present method.

The main field of application of the present method is the field of dye-sensitized solar cells. The photoelectrode of such a type dye solar cell is formed from a porous layer of nanocrystalline semiconductor material which is coated with a dye, for example an organic metal ruthenium dye which strongly absorbs the incident light. The photo-excitation of the dye leads to injecting electrons into the conduction band of the semiconductor material, for example TiO₂. The dye oxidized in this manner takes up the missing electrons from the ions of the electrolyte or from a polymer hole conductor placed between the photoelectrode and a counter electrode which is usually coated with platinum. If an electrolyte having the redox pair I⁻/I₃⁻ is employed, the tri-iodine yielded by the electron donation to the counter electrode is reduced back to iodine again. The whole arrangement is setup as a state-of-the-art sandwich configuration. Due to the porous form of the photoelectrode of the nanocrystalline semiconductor material, the electrolyte is able to penetrate the pores of the photoelectrode in such a manner that a large inner surface is at disposal for the exchange of electrons and thus for the generation of the photocurrent.

### BACKGROUND OF THE INVENTION

In the production of such type dye solar cells, the photoelectrode and the counter electrode are applied as a thin layer using a screen printing technique on a glass substrate coated with a fluorine-doped tin oxide (F:SnO₂) and then fired at approximately 450° C. to 500° C. for thirty minutes. The production of the paste with the nanocrystalline TiO₂ usually occurs by means of controlled hydrolysis of a Ti(IV) compound present either as an alkoxide or as a chloride. One alkoxide that is often used is titanium isopropoxide which either undergoes catalytic hydrolysis or hydrolysis and peptizing in the presence of a peptizing agent, which can be an acid or a base. Such a type sol/gel synthesis, if need be after addition of a binder, yields the paste for the subsequent screen printing for producing the photoelectrode.

A large inner surface, which is provided by the nanoporosity of the photoelectrode, for the electron exchange is of great significance for greater efficiency of the solar cell. Sufficiently fluid electrolytes have good conductivity, whereas the highly viscous electrolytes or the polymer hole conductors recently in use have poor conductivity.

The object of the present invention is to provide a method for producing the photoelectrode of a solar cell as well as a solar cell having a photoelectrode which is producible in this manner and which permits a sufficiently high photocurrent even in the case of highly viscous electrolytes or polymer hole conductors.

### SUMMARY OF THE INVENTION

The object of the present invention is solved with the method and the solar cell according to the claims. Advantageous embodiments of the method and of the cell are the subject matter of the subordinate claims or are contained in the following description and the preferred embodiments.

In the present method for producing the photoelectrode of the solar cell, a layer of a nanocrystalline semiconductor material is applied to a substrate in the state-of-the-art manner and then fired at a sintering temperature. The method is characterized in that elongated particles are introduced into the layer, which burn out at the sintering temperature and leave an elongated cavity (void) in the layer.

The proposed solar cell comprises accordingly, in addition to the counter electrode and the electrolyte or the polymer hole conductor, at least the photoelectrode producible with the method from a nanoporous layer of a semiconductor material which has elongated cavities.

Thus with the present method elongated cavities are produced in the nanoporous semiconductor layer, which as conducting channels increase the conductivity of the electrolyte or of the polymer hole conductor in the nanoporous layer. As sufficient diffusion plays especially in highly viscous electrolytes or polymer hole conductors a significant role for the function of the solar cell, in particular the contact of the redox pair to the semiconductor material, the present method increases the generatable photocurrent and in the same manner the bulk factor of the solar cell. This permits using highly viscous electrolytes or polymer hole conductors, in particular gel-like electrolytes or ionic fluids as electrolytes, also in solar cells with nanoporous photoelectrodes built in this manner.

Another advantage of the present method and of the corresponding solar cell is that adding cavities forms scattering centers in the photoelectrode. The scattering centers increase absorption of the light in the photoelectrode in particular by a dye located in the nanopores on the semiconductor material. The present method therefore results in increased conversion efficiency of a dye solar cell.

In the present method, the elongated particles are preferably introduced into the paste containing the semiconductor material prior to applying the layer. When applying the layer as a paste, for example using a screen printing technique, the particles can easily be mixed with the paste in advance. The material of the particles is selected in such a manner that it burns at the employed sintering temperature so that elongated cavities are left at those sites. All substances that are producible as elongated particles can be used for this purpose, the elongated particles, preferably, having a diameter of between 10 nm and 1 μm. The length of these particles is preferably between 10 nm and 100 μm. The used particles can, for example, be rod-shaped but can also be of any other symmetrical or asymmetrical elongated shape. Particularly advantageous are inexpensive materials, for example fibrous substances or fabric materials. Micrometer thin fibers can easily be shortened to the desired length and mixed with the semiconductor material. Particles of large macromolecules can also be used. The used materials, in particular, plastics such as block-copolymers but also other polymers are selected based on the solvent used in the paste of semiconductor material, the sintering temperature and the desired particle size.

In a similar manner, the amount of elongated particles introduced into the semiconductor material is selected based on the viscosity of the electrolyte and the size of the elongated particles. Preferably, the volume ratio of the elongated particles to the semiconductor material lies in the range of 1:3 to 1:100.

### BRIEF DESCRIPTION OF THE DRAWINGS

The present method and the present solar cell are made more apparent in the following using preferred embodiments with reference to the accompanying drawings without the intention of limiting the scope or spirit of the patent protection set forth by the claims.

FIG. 1 shows a schematic representation of the buildup of a dye solar cell;

FIG. 2 shows a schematic representation to illustrate the present method;

FIG. 3 shows a first example of the buildup of a solar cell having the present photoelectrode;

FIG. 4 shows a second example of the buildup of a solar cell having the present photoelectrode; and

FIG. 5 shows a third example of the buildup of a solar cell having the present photoelectrode.

### DETAILED DESCRIPTION OF THE INVENTION

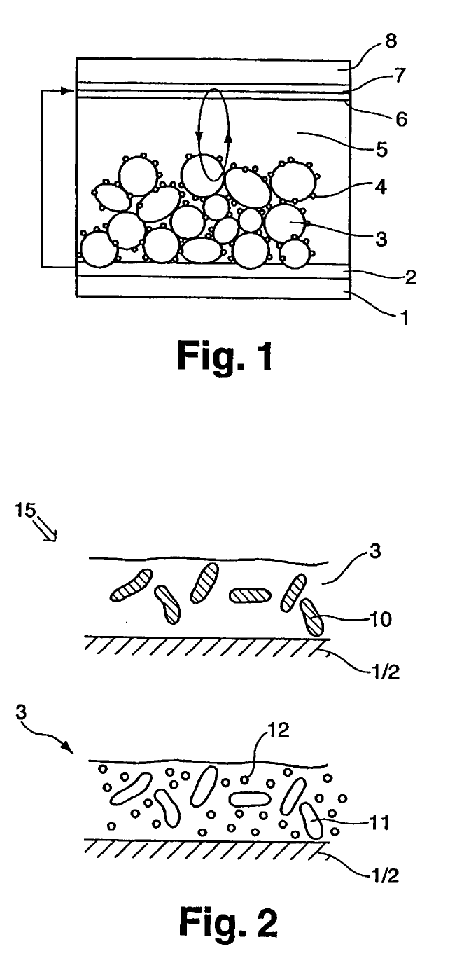

FIG. 1 shows the typical build-up of a dye solar cell as it can also be built according to the present invention. The solar cell is delimited on both sides by two glass substrates 1,8, at the inner sides of each a layer 2,7 of F:SnO₂ is applied. The layer 3 of semiconductor material, in the present example TiO₂, is applied on one of these layers. The cavities generated according to the present method are not shown in the FIGURE. The single nanocrystalline particles of the semiconductor material of layer 3 are coated with a dye 4.

The photoelectrode of the solar cell is formed by the thin layer 3 of the semiconductor material. The counter electrode comprises a platinum coating 6 on the layer 7. Between the photoelectrode and the counter electrode is the I⁻/I₃⁻ electrolyte 5. The process of generating the photocurrent by oxidation of the dye 4 while donating electrons to the conduction band of the semiconductor material (TiO₂) and the return of the electrons via the redox pair I⁻/I₃⁻ was already explained in the introduction of the summary of the invention.

The production of the photoelectrode forming layer 3 according to the present method is explained in more detail in connection with FIG. 2. The layer of semiconductor material is applied as a paste on the F:SnO₂ layer 2 of the glass substrate 1, for example using a screen printing technique 15.

A method based on state-of-the-art sol/gel synthesis of nanocrystalline particles is employed for preparing the paste. First a sol of the TiO₂ used as the semiconductor material is synthesized by means of catalytic hydrolysis of titanium isopropoxides or titanium chlorides or other titanium alkoxides. The colloidal synthesis of TiO₂ is usually accompanied by catalytic hydrolysis of the titanium isopropoxide using acids or bases. For example, 125 ml of titanium isopropoxide is introduced into 750 ml of a 0.1 molar nitric acid or a 0.1 molar acetic acid or a 0.15 molar tetramethyl ammonium hydroxide under strong stirring, forming immediately a white precipitation product, which is then heated at 80° C. for eight hours in order to achieve complete peptization. In order to generate the desired size of the TiO₂ nanoparticles, the peptized sol undergoes a hydrothermic growth process in a titanium autoclave at a temperature of 190° C. to 230° C. for a period of twelve hours. Then the formed particles are washed with ethanol and redispersed in the presence of an organic tenside with the aid of a titanium ultrasonic horn. After ultrasonic treatment, the yielded solution is concentrated using a rotation evaporator and mixed with CARBOWAX® 20000 or mixed to a paste that can be employed in screen printing by adding ethyl cellulose or terpene alcohol (terpineol). In the present example, polymer nanotubes of block polymers are mixed into this paste. These polymer nanotubes (cf. e.g. J. Grumelard et al., “Soft Nanotubes from Amphilic ABA Triblock Macromonomers”, Chem. Commun., 2004, pp. 1462-1463) are homogeneously mixed with the paste in a volume ratio of 1:5 to the paste material. Mixing preferably occurs in a ultrasonic bath at room temperature.

The upper part of FIG. 2 shows the paste with the introduced nanotubes 10 as the layer 3 applied to substrate 1. The substrate 1 is then sintered with this layer 3 at 450° C. in order to remove the organic solvent from the paste. The introduced nanotubes 10 also burn out at this high temperature so that elongated cavities 11 are left at their sites, as indicated in the lower detail of FIG. 2. This detail shows the layer 3 sintered at the sintering temperature T_{S} utilized as the photoelectrode in the solar cell. In this solar cell layer, the nanopores 12 are now also formed in the semiconductor material. In the same manner, the layer is applied on the substrate 1 with a layer thickness of approximately 10 μm. In producing the solar cell, this layer is introduced in a state-of-the-art manner in a bath containing the to-be-applied metal organic ruthenium dye so that the latter deposits inside the layer on the surface of the nanocrystalline TiO₂ particles.

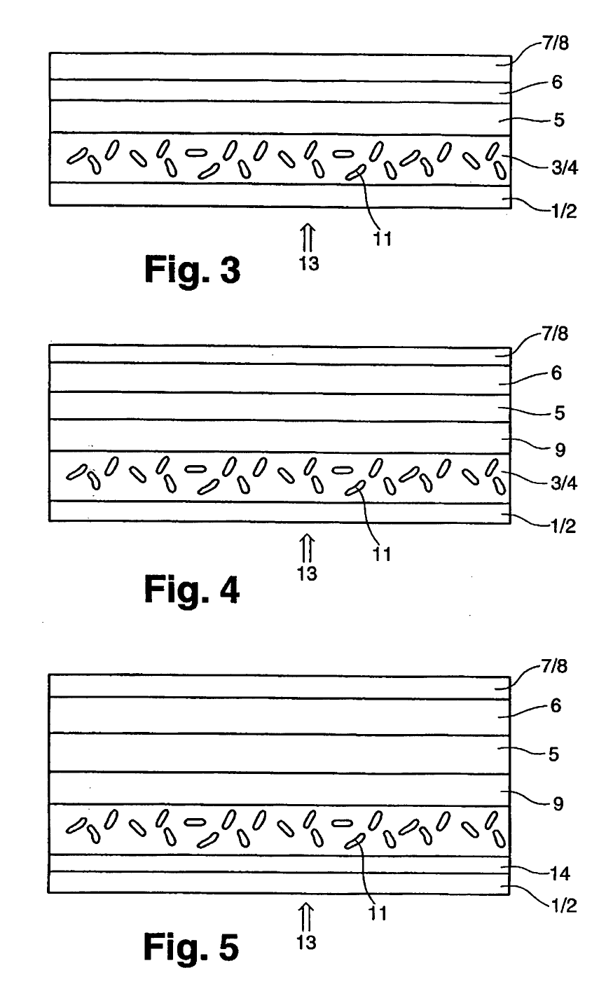

FIG. 3 shows, as an example and greatly schematized, a sandwich build-up of a solar cell as it can also be employed in the present solar cell. This build-up corresponds to the build-up of the already elucidated FIG. 1. The electrolyte 5, which is disposed in this case between the counter electrode, the platinum layer 6, and the photoelectrode produced according to the present method, the semiconductor layer 3 with the dye 4, passes through both the nanopores of the semiconductor layer 3 and the elongated cavities 11 contained therein. The sunlight 13 passing through the glass substrate 1 is additionally scattered by these cavities 11 so that a greater part of the incident light can be absorbed by the dye 4.

FIG. 4 shows another possible preferred embodiment of the solar cell in which, in addition, a back-scattering layer 9 is applied to the nanoporous layer 3 in order to reflect the incident sunlight 13 which passes through the semiconductor layer 3 back into the layer 3. In this case too, the layer 3 has been produced according to the present method. The additional back-scattering layer 9 is composed of a zirconium dioxide or a titanium dioxide (rutile), which are already known for such use.

Finally FIG. 5, shows a further example of a solar cell in which the photoelectrode was produced according to the present method and has the corresponding elongated cavities 11. In this embodiment, in addition a compact thin TiO₂ layer 14 is placed between the layer 3 and the glass substrate 1. The compact thin TiO₂ layer 14 serves to block the back reaction from the substrate into the electrolyte.

### LIST OF REFERENCES FOR FIGURES

1—Glass substrate

2—F:SnO₂ layer

3—Semiconductor layer (photoelectrode)

4—Dye

5—Electrolyte

6—Platinum layer (counter electrode)

7—F:SnO₂ layer

8—Glass substrate

9—Back-scattering layer

10—Nanotubes

11—Elongated cavities

12—Nanopores

13—Light

14—Another TiO₂ layer

15—Screen printing process

What is claimed is:

1. A method for producing a photoelectrode of a solar cell comprising applying a layer of a nanocrystalline semiconductor material on a substrate and then sintering at a sintering temperature, and introducing elongated particles into the layer which burn out at the sintering temperature and leave elongated cavities in the layer.

2. A method according to claim 1, wherein said elongated particles comprise fibers.

3. A method according to claim 1, wherein the elongated particles have a diameter of 10 nm to 1 μm.

4. A method according to claim 1, wherein the elongated particles have a length of 10 nm to 100 μm.

5. A method according to claim 1, wherein the elongated particles comprise a plastic material.

6. A method according to claim 1, wherein the layer comprises a paste and said introducing of the elongated particles into the layer comprises introducing said elongated particles into the paste before said applying of said layer on the substrate.

7. A method according to claim 1, wherein the semiconductor material comprises TiO₂ or a mixture containing TiO₂.

8. A method according to claim 1, wherein said introducing of the elongated particles into the layer is in a volume ratio of 1:3 to 1:100 to the semiconductor material.

9. A solar cell having a photoelectrode produced according to the method of any one of claims 1 to 8 comprising a nanoporous layer of a semiconductor material, a counter electrode and an electrolyte or a polymer hole conductor, which passes through the nanporous layer, between the photoelectrode and the counter electrode, wherein the layer of the semiconductor material has elongated cavities.

10. A solar cell according to claim 9, wherein the electrolyte is present as a gel or as an ionic fluid.

11. A solar cell according to claim 9, wherein the elongated cavities have a diameter of 10 nm to 1 μm and a length of up to 100 μm.

12. A solar cell according to claim 9, wherein the elongated cavities are present in the layer in a volume ratio of 1:3 to 1:100 to the semiconductor material.
